(19) United States
(12) Patent Application Publication
(10) Pub. No.: US 2012/0268566 A1
(43) Pub. Date: Oct. 25, 2012

(54) THREE-DIMENSIONAL COLOR IMAGE SENSORS HAVING SPACED-APART MULTI-PIXEL COLOR REGIONS THEREIN

(75) Inventors: Won-Joo Kim, Hwaseong-si (KR); Yoon-Dong Park, Yongin-si (KR); Hyoung-Soo Ko, Hwaseong-si (KR)

(73) Assignee: Samsung Electronics Co., Ltd.

(21) Appl. No.: 13/450,761

(22) Filed: Apr. 19, 2012

(30) Foreign Application Priority Data
Apr. 21, 2011 (KR) 10-2011-0037096

(51) Int. Cl. H04N 13/02

(52) U.S. Cl. 348/46; 348/E13.074

(57) ABSTRACT

A three-dimensional color image sensor includes color pixels and depth pixels therein. A semiconductor substrate is provided with a depth region therein, which extends adjacent a surface of the semiconductor substrate. A two-dimensional array of spaced-apart color regions are provided within the depth region. Each of the color regions includes a plurality of different color pixels therein (e.g., red, blue and green pixels) and each of the color pixels within each of the spaced-apart color regions are spaced-apart from all other color pixels within other color regions.

### REFERENCE TO PRIORITY APPLICATION

This application claims priority under 35 USC §119 to Korean Patent Application No. 10-2011-0037096, filed Apr. 21, 2011, the disclosure of which is hereby incorporated herein by reference.

### FIELD

The present invention relates to integrated circuit devices and, more particularly, integrated image sensors having three-dimensional (3D) image sensor capability.

### BACKGROUND

An image sensor is a device configured to convert optical signals for providing image information of the captured image to electrical signals. Research and development is in progress to enhance the quality of the image captured by the image sensor. Particularly much works are in progress to improve performance of a three-dimensional image sensor for providing depth information or distance information representing a distance to an object in addition to the image information of the object.

### SUMMARY

Three-dimensional color image sensors according to embodiments of the invention include color pixels and depth pixels therein. According to some of these embodiments of the invention, a semiconductor substrate is provided with a depth region therein, which extends adjacent a surface of the semiconductor substrate. A two-dimensional array of spaced-apart color regions are provided within the depth region. Each of the color regions includes a plurality of different color pixels therein (e.g., red, blue and green pixels). Moreover, each of the color pixels within each of the spaced-apart color regions is spaced-apart from all other color pixels within other color regions. The depth region also includes a plurality of depth pixels therein. This depth region is configured so that each of the color regions is surrounded on all sides by the depth region. Each of the spaced-apart color regions may include a blue pixel, a red pixel and a plurality of green pixels and each green pixel in one color region is separated from a green pixel in another color region by at least one depth pixel.

### BRIEF DESCRIPTION OF THE DRAWINGS

Illustrative, non-limiting example embodiments will be more clearly understood from the following detailed description taken in conjunction with the accompanying drawings.

FIG. 1 is a diagram illustrating a pixel array of a three-dimensional image sensor according to example embodiments.

FIG. 2 is a diagram illustrating an example layout of a pixel array according to example embodiments.

FIGS. 3a, 3b, 3c, 3d and 4 are circuit diagrams illustrating unit pixels in a pixel array.

FIG. 5 is a cross-sectional diagram illustrating an example structure of a pixel array according to example embodiments.

FIGS. 6, 7, 8a, 8b, 9a, 9b, 10a, 10b, 11a, 11b and 12 are diagrams illustrating example layouts of a pixel array according to example embodiments.

FIG. 13 is a diagram illustrating a layout of color pixels in a color region according to example embodiments.

FIG. 14 is a diagram illustrating an equivalent circuit of the color pixels of FIG. 13.

FIGS. 15, 16, 17a and 17b are diagrams illustrating example layouts of a pixel array according to example embodiments.

FIG. 18 is a block diagram illustrating a photo-detection device according to example embodiments.

FIG. 19 is a diagram illustrating an example of a sensing unit in the three-dimensional image sensor of FIG. 18.

FIG. 20 is a block diagram illustrating a camera including a three-dimensional sensor according to example embodiments.

FIG. 21 is a block diagram illustrating a computing system including a three-dimensional sensor according to example embodiments.

FIG. 22 is a block diagram illustrating an interface employable in the computing system of FIG. 21.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

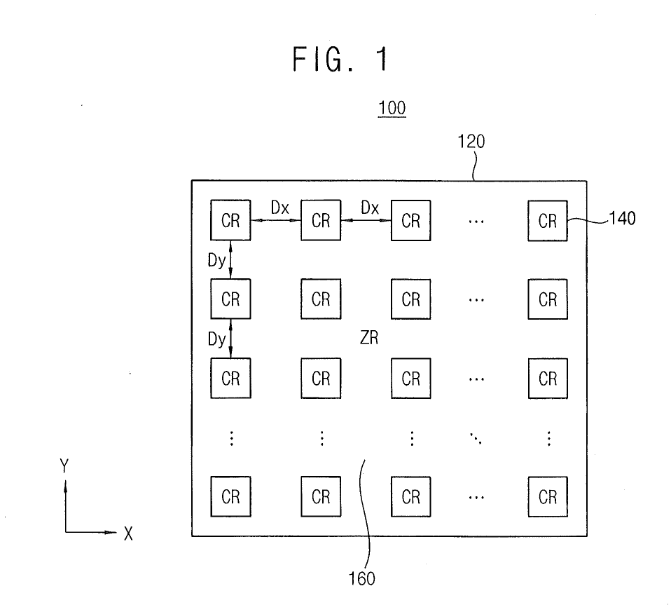

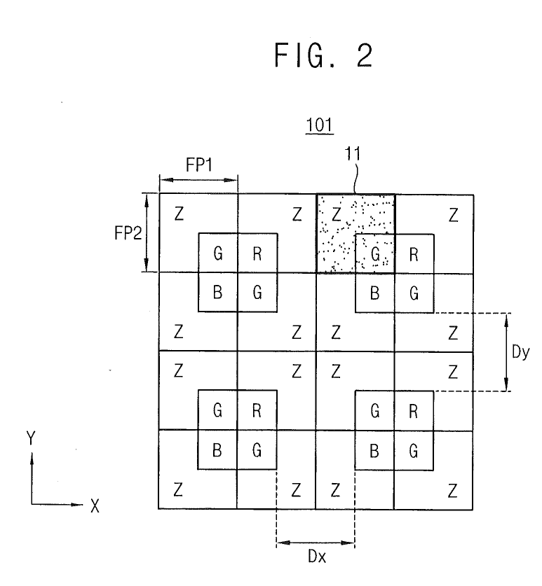

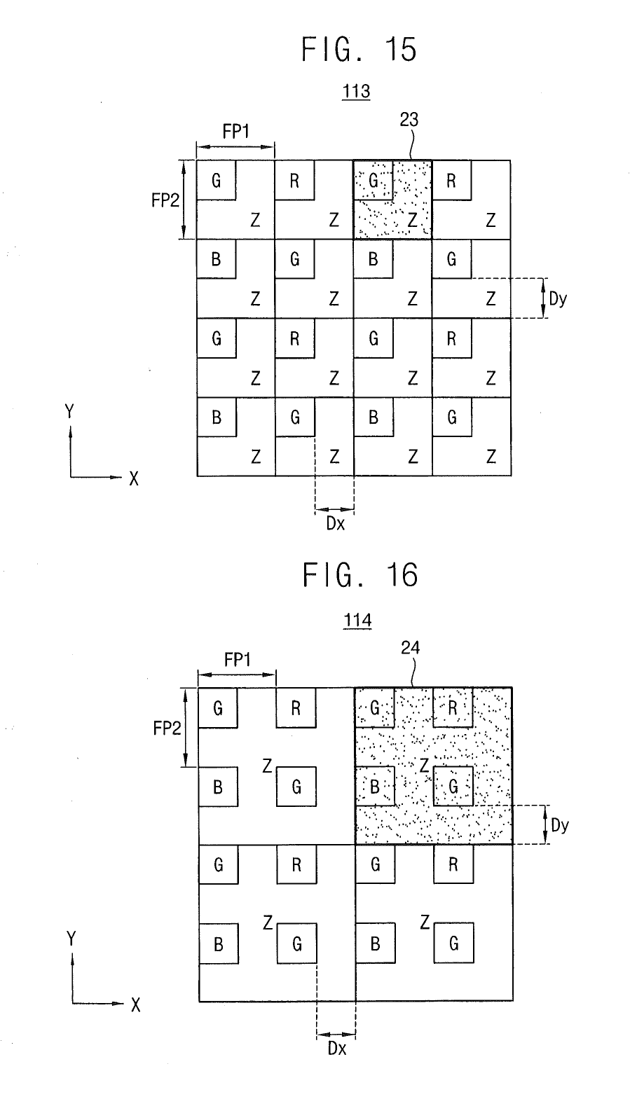

FIG. 1 is a diagram illustrating a pixel array of a three-dimensional image sensor according to example embodiments. FIG. 1 illustrates a conceptual layout of a pixel array 100 integrated in a pixel array region 120 of a semiconductor substrate. Referring to FIG. 1, the pixel array region 120 includes color regions CR and a depth region ZR. The color regions CR are spaced apart from each other by a first interval Dx in a row direction X and by a second interval Dy in a column direction Y. The depth region ZR corresponds to an empty region outside the color regions CR in the pixel array region 120. The color regions CR are regularly arranged in a matrix form of rows and columns, and the depth region ZR surrounds each of the color regions CR. At least one color pixel may be included in each color region CR. For example, four color pixels may be included in each color region CR and arranged in a matrix form of two rows and two columns as illustrated in FIGS. 2, 6, 7, 8a-8b, 9a-9b, 10a-10b, 11a-11b and 12, or one color pixel may be included in each color region CR as illustrated in FIGS. 15, 16, 17a and 17b. The number and the pattern of the color pixels in each color region CR may be determined variously other than the illustrated non-limiting examples. To maintain regularity of entire pattern, the color regions have the uniform intervals Dx and Dy in the row and column directions X and Y, and the number and the pattern in each color region CR are uniform with respect to all of the color regions CRs.

The depth region ZR may be partitioned regularly and one depth pixel may be included in each partitioned region. As will be further described, the pixel array region 120 may be partitioned into a plurality of unit regions by uniformly-spaced horizontal lines and vertical lines. Each unit region has a rectangular shape and includes the one depth pixel and the at least one color pixel such that a number ratio and an area ratio of the one depth pixel and the at least one color pixel in each unit region are uniform with respect to all of the unit regions. As such, the quality of the image provided by the pixel array 100 may be enhanced by realizing the uniform color pixel pattern and the uniform depth pixel pattern with regularly formed color pixels and depth pixels.

In general, the depth pixel occupies a relatively large area compared with the color pixel because the sensitivity is more important than the resolution with respect to the depth pixel. In designing the pixel array 100 according to example embodiments, firstly the color pixels of the uniform pattern are arranged in the uniformly-spaced color regions CRs and then the depth pixels of the uniform pattern are arranged in the partitioned depth region ZR. Thus the occupation area of the depth pixel may be adjusted conveniently without affecting the pattern of the color pixels.

FIG. 2 is a diagram illustrating an example layout of a pixel array according to example embodiments. For convenience of illustration, a portion of the pixel array region 120 of FIG. 1 is illustrated in FIG. 2. As described with reference to FIG. 1, a pixel array 101 includes a plurality of color pixels R, G and B formed in the color regions and a plurality of depth pixels Z formed in the depth region. The color regions are spaced apart from each other by a first interval Dx in a row direction X and by a second interval Dy in a column direction Y. The depth region corresponds to the empty region outside the color regions in the pixel array region. Referring to FIG. 2, each color region includes the four color pixels G, R, B and G arranged in a matrix form of two rows and two columns. The four color pixels G, R, B and G in each color region may form a color cluster for representing various colors. The non-limiting example embodiment is illustrated in FIG. 2, in which each color region includes two green pixels G, one red pixel R and one blue pixel B. In other example embodiments, each color region may include at least one pixel among red pixels R, green pixels G, blue pixels B, magenta pixels Mg, cyan pixels Cy, yellow pixels Y, white pixels W, etc. The pixel array region may be partitioned into a plurality of unit regions, and each unit region of the rectangular shape may include one depth pixel Z and one or more color pixels R, G and B. For example, the pixel array region may be partitioned by uniformly-spaced horizontal lines and vertical lines so that each unit region defined by the two adjacent horizontal lines and the two adjacent vertical lines has the rectangular shape. A number ratio and an area ratio of the depth pixel and the color pixels in each unit region may be uniform with respect to all of the unit regions.

FIG. 2 illustrates sixteen unit regions arranged in a matrix form of four rows and four columns. As an example, one unit region 11 is represented as the dotted rectangular region in FIG. 2. Each unit region 11 may include the one depth pixel Z and one of the color pixels R, G and B, and the one color pixel may be disposed at one of four corner portions of each unit region 11. As such, the unit regions 11 are repeatedly disposed in the row direction X and in the column direction Y, and the number ratio of the depth pixel and the color pixel in each unit region 11 corresponds to 1:1 with respect to all of the unit regions. In addition, the area ratio of the depth pixel and the color pixel in each unit region 11 is uniform with respect to all of the unit regions 11. In general, the pixel array is designed such that the pixel array region is partitioned into standard cells defined by a row unit length FP1 and a column unit length FP2, and one depth pixel and/or one color pixel is assigned to each standard cell. In this case, the pattern of the color pixels has to be damaged to increase the area of the depth pixel.

In comparison, according to example embodiments, firstly the color pixels of the uniform pattern are arranged in the uniformly-spaced color regions CRs and then the depth pixels of the uniform pattern are arranged in the partitioned depth region ZR as described with reference to FIG. 1. As such, uniform patterns of the depth pixels Z and the color pixels R, G and B may be achieved to enhance the quality of the image provided by the pixel array 101, and the occupation area of the depth pixel Z may be adjusted conveniently by variously partitioning the depth region ZR corresponding to the empty region except the color regions CRs without affecting the pattern of the color pixels R, G and B.

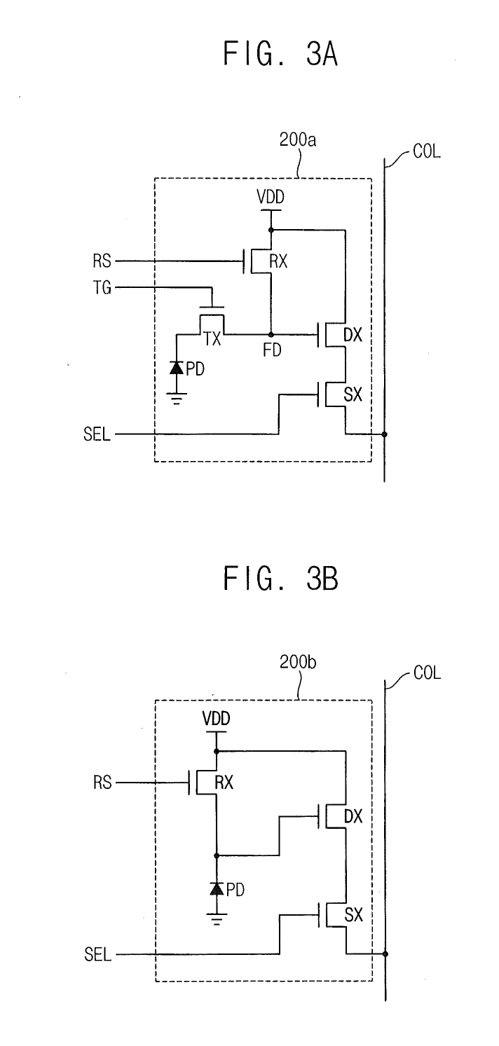

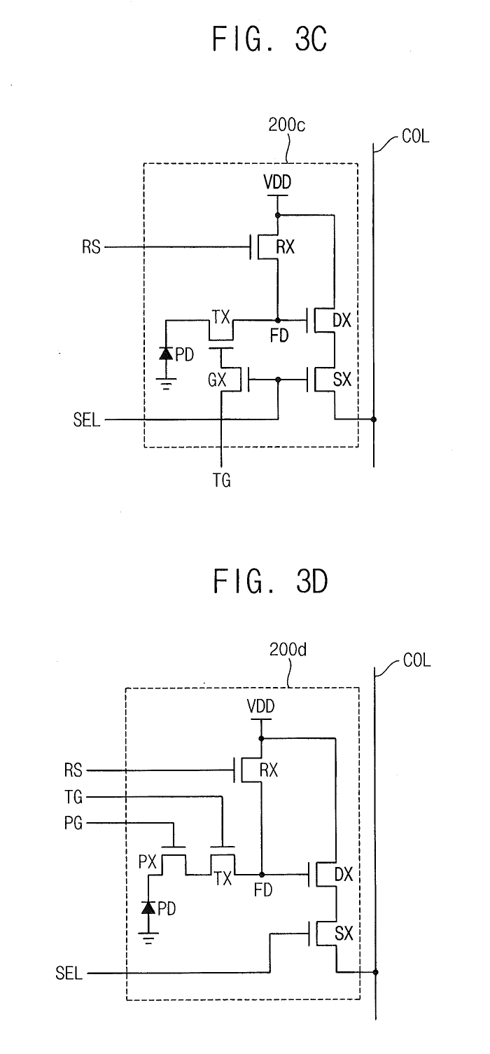

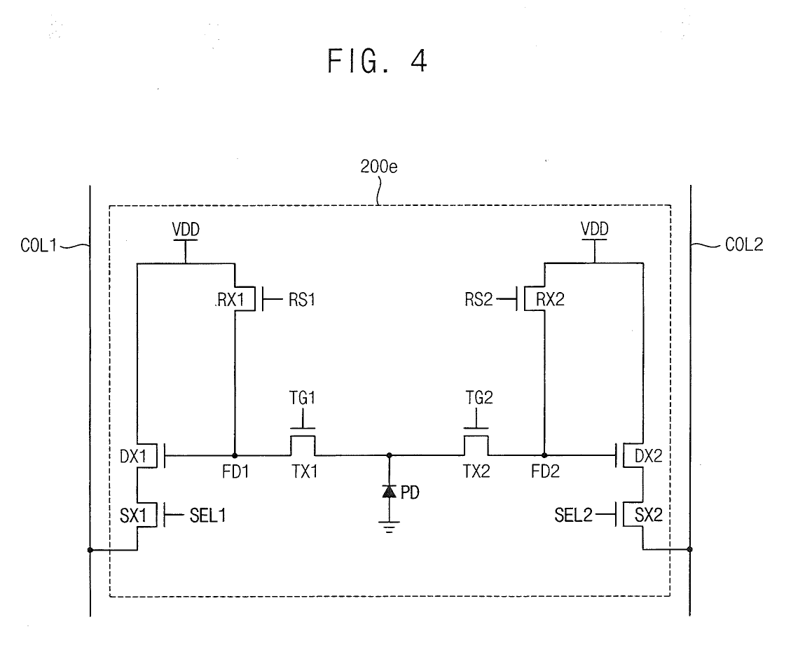

FIGS. 3a-3d and 4 are circuit diagrams illustrating unit pixels in a pixel array. The unit pixels 200a, 200b, 200c, 200d and 200e illustrated in FIGS. 3a-3d and 4 may be various color pixels for providing the image information or a depth pixel for providing the distance/depth information. Referring to FIG. 3a, the unit pixel 200a may include a photo-sensitive element such as a photodiode PD, and a readout circuit including a transfer transistor TX, a reset transistor RX, a drive transistor DX and a selection transistor SX. For example, the photodiode PD may include an n-type region in a p-type substrate such that the n-type region and the p-type substrate form a p-n junction diode. The photodiode PD receives the incident light and generates a photo-charge based on the incident light. In some example embodiments, the unit pixel 200a may include a photo transistor, a photo gate, a pinned photo diode, etc. instead of or in addition to the photodiode PD. The photo-charge generated in the photodiode PD may be transferred to a floating diffusion node FD through the transfer transistor TX, which is turned on in response to a transfer control signal TG. The drive transistor DX functions as a source follower amplifier that amplifies a signal corresponding to the charge on the floating diffusion node FD. The selection transistor SX may transfer the amplified signal to a column line COL in response to a selection signal SEL. The floating diffusion node FD may be reset by the reset transistor RX. For example, the reset transistor RX may discharge the floating diffusion node FD in response to a reset signal RS for correlated double sampling (CDS).

FIG. 3a illustrates the unit pixel 200a of the four-transistor configuration including the four transistors TX, RX, DX and SX. The configuration of the unit pixel may be variously changed as illustrated in FIGS. 3b, 3c and 3d. Referring to FIG. 3b, the unit pixel 200b may have the three-transistor configuration including a photo-sensitive element such as a photodiode PD, and a readout circuit including a reset transistor RX, a drive transistor DX and a selection transistor SX. Compared with the unit pixel 200a of FIG. 3a, the transfer transistor TX is omitted in the unit pixel 200b of FIG. 3b. Referring to FIG. 3c, the unit pixel 200c may have the five-transistor configuration including a photo-sensitive element such as a photodiode PD, and a readout circuit including a transfer transistor TX, a gate transistor GX, a reset transistor RX, a drive transistor DX and a selection transistor SX. The gate transistor GX may selectively apply the transfer control signal TG to the transfer transistor TX in response to the selection signal SEL. Referring to FIG. 3d, the unit pixel 200d may have the five-transistor configuration including a photo-sensitive element such as a photodiode PD, and a readout circuit including a photo transistor PX, a transfer transistor TX, a reset transistor RX, a drive transistor DX and a selection transistor SX. The photo transistor PX may be turned on or off in response to a photo gate signal PG. The unit pixel 200d may enabled when the photo transistor PX is turned on and disabled when the photo transistor PX is turned off.

At least a portion of the unit pixel may be shared by the other unit pixels. For example, each unit pixel of FIG. 3a may include the respective photodiode PD and the respective transfer transistor TX dedicated to the corresponding unit pixel, and the other elements such as the floating diffusion node FD, the reset transistor RX and the selection transistor SX may be shared by two or more unit pixels. The unit pixel 200e of FIG. 4 has a two-tap configuration compared with the single-tap configuration of the unit pixels 200a, 200b, 200c and 200d of FIGS. 3a, 3b, 3c and 3d. Thus the unit pixel 200e may be used as the depth pixel to measure the distance to an object in the time-of-flight (TOF) scheme. Referring to FIG. 4, the unit pixel 200e may include a photo-sensitive element such as a photodiode PD, a first readout circuit including a first transfer transistor TX1, a first reset transistor RX1, a first drive transistor DX1 and a first selection transistor SX1, and a second readout circuit including a second transfer transistor TX2, a second reset transistor RX2, a second drive transistor DX2 and a second selection transistor SX2. The photodiode PD may include an n-type region in a p-type substrate such that the n-type region and the p-type substrate form a p-n junction diode. The photodiode PD receives the incident light and generates a photo-charge based on the incident light. In some example embodiments, the unit pixel 200e may include a photo transistor, a photo gate, a pinned photo diode, etc. instead of or in addition to the photodiode PD.

The photo-charge generated in the photodiode PD may be transferred to floating diffusion nodes FD1 and FD2 through the transfer transistors TX1 and TX2, respectively. The first transfer control signal TG1 and the second transfer control signal TG2 may be activated complementarily. For example, when the first transfer control signal TG1 has a first logic level (e.g., a logic high level) and the second transfer control signal TG2 has a second logic level (e.g., a logic low level), the first transfer transistor TX1 is turned on and the second transfer TX2 is turned off so that the charge may be transferred from the photodiode PD to the first floating diffusion node FD1 through the first transfer transistor TX1. In contrast, when the first transfer control signal TG1 has the second logic level (e.g., the logic low level) and the second transfer control signal TG2 has the first logic level (e.g., the logic high level), the first transfer transistor TX1 is turned off and the second transfer TX2′ is turned on so that the charge may be transferred from the photodiode PD to the second floating diffusion node FD2 through the second transfer transistor TX2. Based on this configuration, the photo charge generated in the photodiode PD may be divided in response to the complementary control signals TG1 and TG2 to determine the roundtrip time-of-flight (TOF) of emitted light, which enables the distance between the unit pixel 200e and the object to be calculated. The drive transistors DX1 and DX2 function as source follower amplifiers that amplify signals corresponding to the respective charges on the floating diffusion nodes FD1 and FD2. The selection transistors SX1 and SX2 may transfer the amplified signals to the column lines COL1 and COL2 in response to the selection signals SEL1 and SEL2, respectively. The floating diffusion nodes FD1 and FD2 may be reset by the reset transistors RX1 and RX2. For example, the reset transistors RX1 and RX2 may discharge the floating diffusion nodes FD1 and FD2 in response to the reset signals RS1 and RS2, respectively, for correlated double sampling (CDS). FIG. 4 illustrates a non-limiting example of a depth pixel having a two-tap configuration, but other configurations of depth pixels may have a single-tap configuration, a four-tap configuration, etc.

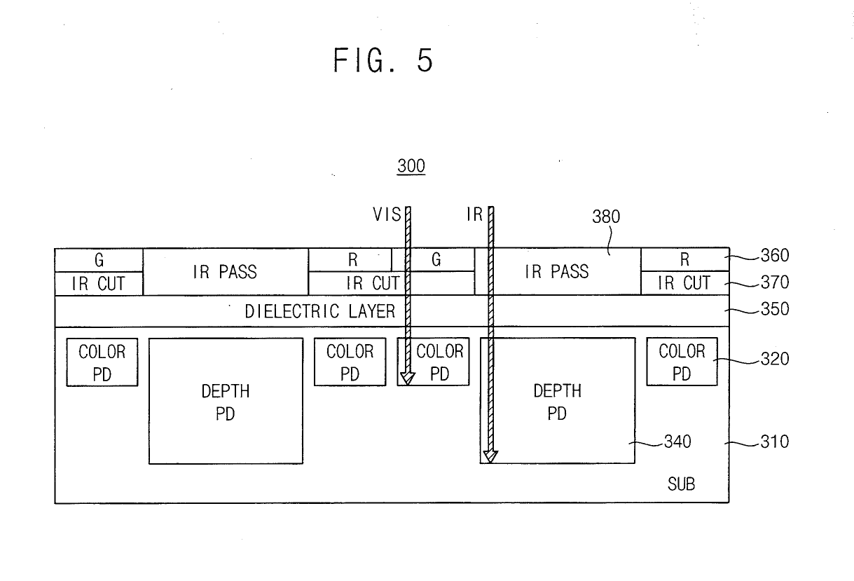

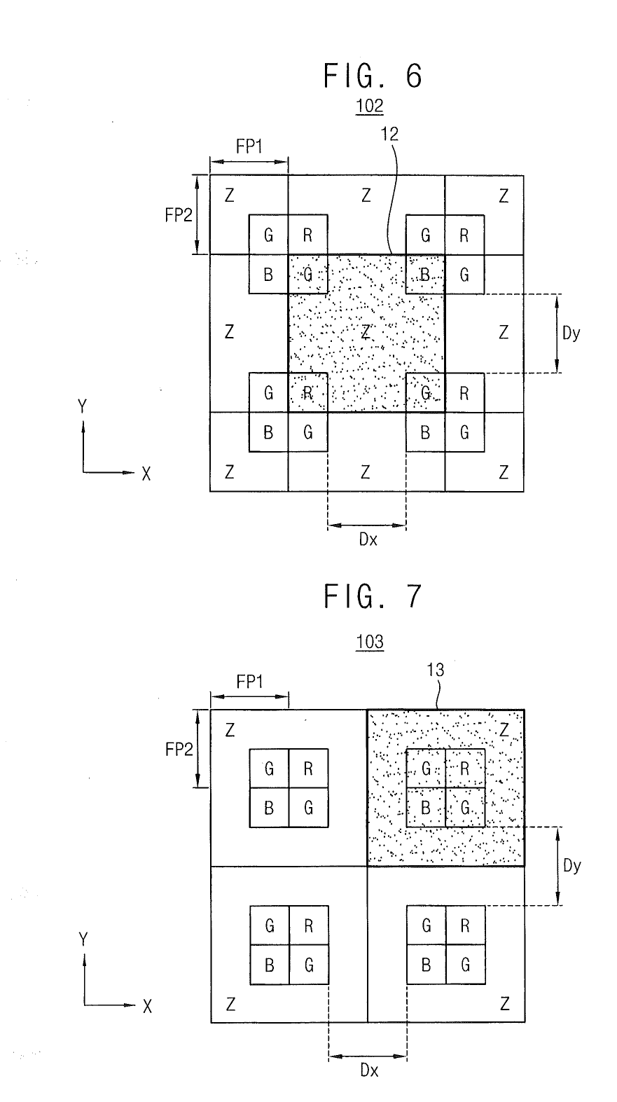

FIG. 5 is a cross-sectional diagram illustrating an example structure of a pixel array according to example embodiments. Referring to FIG. 5, the pixel array 300 may include a first photodiode 320 and a second photodiode 340 formed in a semiconductor substrate 310. The first photodiode 320 may be included in each of the color pixels R, G and B of FIG. 2, and the second photodiode 340 may be included in each of the depth pixels Z. The second photodiode 340 requiring higher sensitivity for the distance information may have a larger occupation area than the first photodiode 320, which captures image information. The first photodiode 320 is formed in the above-mentioned color regions CR to convert the incident visible light VIS to an electrical signal. The first photodiode 320 may correspond to an n-well formed by implanting n-type impurities into the semiconductor substrate 310. The second photodiode 340 is formed in the above-mentioned depth region ZR to convert the incident infrared light IR to an electrical signal. The second photodiode 340 may correspond to an n-well formed by implanting n-type impurities into the semiconductor substrate 310. Considering the characteristics of the visible light VIS and the infrared light IR, the second photodiode 340 may be configured to have a larger depth and a higher doping density than the first photodiode 320. Moreover, the second photodiode 340 may have larger occupation area than the first photodiode 320, and the area ratio of the second photodiode 340 and the first photodiode 320 may be determined variously. As will be described with reference to FIGS. 6, 7, 8a-8b, 9a-9b, 10a-10b, 11a-11b and 12, the area ratio of the second photodiode 340 and the first photodiode 320 and thus the area ratio of the one depth pixel and the at least one color pixel in each unit region may be determined depending on the size of the unit region. The area of the second photodiode 340 of the depth pixel may be increased to enhance the sensitivity of the depth pixel. Even though the resolution of distance measurement may be degraded, the signal-to-noise ratio (SNR) may be improved by increasing the area of the depth pixel.

The pixel array 300 may further include a dielectric layer 350 and filters 360, 370 and 380. Gates of the transistors in the readout circuit, metal wires, etc. may be formed in the dielectric layer 350. The color filter 360 and the IR cut filter 370 may be formed on a first portion of the dielectric layer extending opposite the first photodiode 320 and the IR pass filter 380 may be formed on a second portion of the dielectric layer extending opposite the second photodiode 340. The pixel array 300 may further include a global filter (not illustrated) formed on the illustrated filters 360, 370 and 380.

FIGS. 6, 7, 8a-8b, 9a-9b, 10a-10b, 11a-11b and 12 are diagrams illustrating example layouts of a pixel array according to additional embodiments. As described with reference to FIGS. 1 and 2, the pixel arrays in FIGS. 6, 7, 8a-8b, 9a-9b, 10a-10b, 11a-11b and 12 include the plurality of color pixels R, G and B formed in the color regions CR and the plurality of depth pixels Z formed in the depth region ZR. The color regions are spaced apart from each other by the first interval Dx in the row direction X and by the second interval Dy in the column direction Y. The depth region ZR corresponds to the empty region except the color regions CR in the pixel array region 120. As with the embodiment of FIG. 2, each color region includes the four color pixels G, R, B and G arranged in a matrix form of two rows and two columns in the embodiments of FIGS. 6, 7, 8a-8b, 9a-9b, 10a-10b, 11a-11b and 12. As represented by the various embodiments, the depth region ZR may be partitioned variously. In other words, the unit region may be defined variously, and the pattern of the depth pixels may be determined depending on the definition of the unit region.

Referring to FIG. 6, the pixel array 102 may be partitioned into unit regions such that each unit region is four times larger than a standard cell that is defined by a row unit length FP1 and a column unit length FP2. For convenience of illustration, one unit region 12 is represented as the dotted rectangular in FIG. 6. Each unit region 12 has a row-directional length of 2*FP1 and a column-directional length of 2*FP2. Each unit region 12 includes the one depth pixel Z and the four color pixels G, B, R and G, and the four color pixels G, B, R and G are disposed at four corner portions of each unit region 12, respectively. In other words, the four pixels G, B, R and G included in the four different color regions are disposed at the four corner portions of each unit region 12. Accordingly, the unit regions 12 are repeatedly disposed in the row direction X and in the column direction Y, and the number ratio of the depth pixel and the color pixel in each unit region 12 corresponds to 1:4 with respect to all of the unit regions 12. In addition, the area ratio of the depth pixel and the color pixels in each unit region 12 is uniform with respect to all of the unit regions 12.

Referring to FIG. 7, the pixel array 103 may be partitioned into unit regions such that each unit region is four times larger than the standard cell that is defined by the row unit length FP1 and the column unit length FP2. For convenience of illustration, one unit region 13 is represented as the dotted rectangular in FIG. 7. Each unit region 13 has a row-directional length of 2*FP1 and a column-directional length of 2*FP2. Each unit region 13 includes the one depth pixel Z and the four color pixels G, R, B and G, and the four color pixels G, R, B and G are disposed at a center portion of each unit region 13. In other words, the four pixels G, R, B and G included in the one color region are disposed at the center portion of each unit region 13. Accordingly, the unit regions 13 are repeatedly disposed in the row direction X and in the column direction Y, and the number ratio of the depth pixel and the color pixel in each unit region 13 corresponds to 1:4 with respect to all of the unit regions 13. In addition, the area ratio of the depth pixel and the color pixels in each unit region 13 is uniform with respect to all of the unit regions 13.

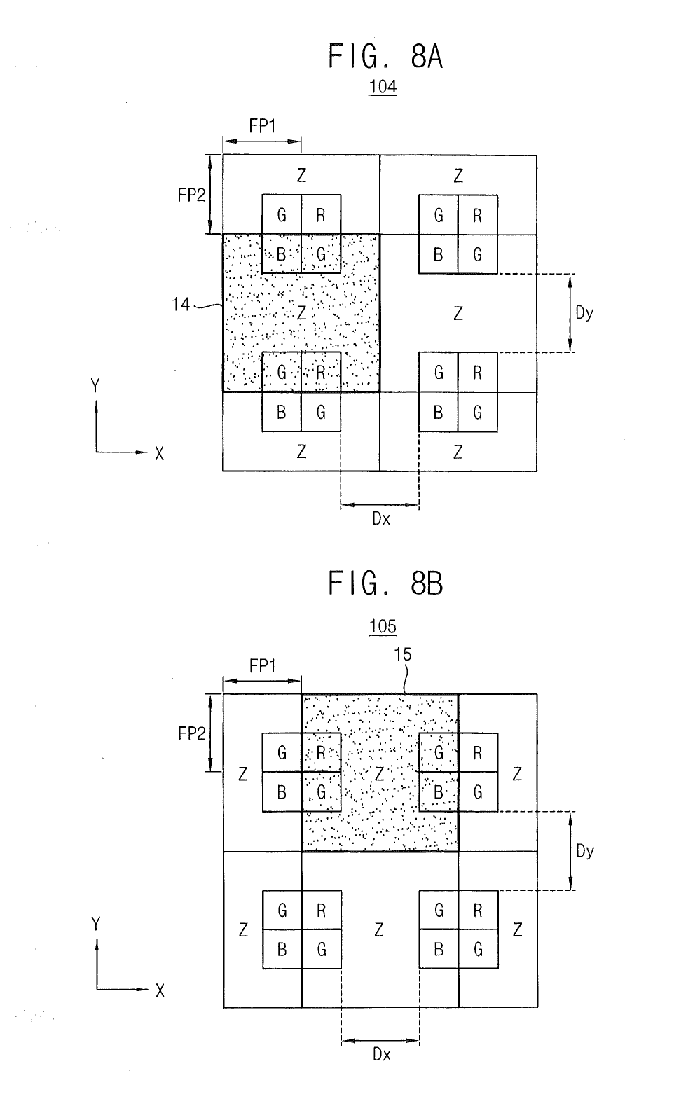

Referring to FIG. 8a, the pixel array 104 may be partitioned into unit regions such that each unit region is four times larger than the standard cell that is defined by the row unit length FP1 and the column unit length FP2. For convenience of illustration, one unit region 14 is represented as the dotted rectangular in FIG. 8a, Each unit region 14 has a row-directional length of 2*FP1 and a column-directional length of 2*FP2. Each unit region 14 includes the one depth pixel Z and the four color pixels B, G, G and R, and the four color pixels B, G, G and R are disposed at upper and bottom side portions of each unit region 14 two by two. In other words, the two pixels B and G included in the upper color region are disposed at the upper side portion of each unit region 14 and the two pixels G and R included in the bottom color region are disposed at the bottom side portion of each unit region 14. Accordingly, the unit regions 14 are repeatedly disposed in the row direction X and in the column direction Y, and the number ratio of the depth pixel and the color pixel in each unit region 14 corresponds to 1:4 with respect to all of the unit regions 14. In addition, the area ratio of the depth pixel and the color pixels in each unit region 14 is uniform with respect to all of the unit regions 14.

Referring to FIG. 8b, the pixel array 105 may be partitioned into unit regions such that each unit region is four times larger than the standard cell that is defined by the row unit length FP1 and the column unit length FP2. For convenience of illustration, one unit region 15 is represented as the dotted rectangular in FIG. 8b. Each unit region 15 has a row-directional length of 2*FP1 and a column-directional length of 2*FP2. Each unit region 15 includes the one depth pixel Z and the four color pixels R, G, G and B, and the four color pixels R, G, G and B are disposed at right and left side portions of each unit region 15 two by two. In other words, the two pixels G and B included in the right color region are disposed at the right side portion of each unit region 15 and the two pixels R and G included in the left color region are disposed at the left side portion of each unit region 15. Accordingly, the unit regions 15 are repeatedly disposed in the row direction X and in the column direction Y, and the number ratio of the depth pixel and the color pixel in each unit region 15 corresponds to 1:4 with respect to all of the unit regions 15. In addition, the area ratio of the depth pixel and the color pixels in each unit region 15 is uniform with respect to all of the unit regions 15.

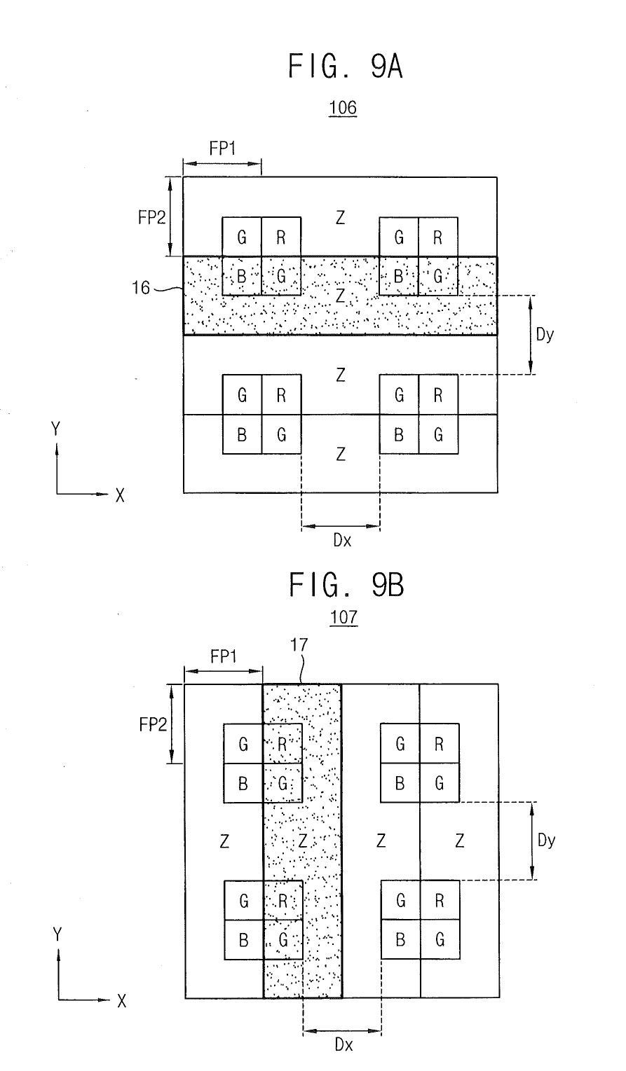

Referring to FIG. 9a, the pixel array 106 may be partitioned into unit regions such that each unit region is four times larger than the standard cell that is defined by the row unit length FP1 and the column unit length FP2. For convenience of illustration, one unit region 16 is represented as the dotted rectangular in FIG. 9a. Each unit region 16 has a row-directional length of 4*FP1 and a column-directional length of FP2. Each unit region 16 includes the one depth pixel Z and the four color pixels and the four color pixels are disposed at one side portion of each unit region 16. In other words, the four color pixels B, G, B and G included in the two upper color regions are disposed at the upper side portion of the dotted unit region 16 and the four color pixels G, R, G and R included in the two bottom color regions are disposed at the bottom side portion of the unit regions that are adjacent to the dotted unit region 16 in the column direction Y. Accordingly, the unit regions 16 are repeatedly disposed in the row direction X and in the column direction Y, and the number ratio of the depth pixel and the color pixel in each unit region 16 corresponds to 1:4 with respect to all of the unit regions 16. In addition, the area ratio of the depth pixel and the color pixels in each unit region 16 is uniform with respect to all of the unit regions 16.

Referring to FIG. 9b, the pixel array 107 may be partitioned into unit regions such that each unit region is four times larger than the standard cell that is defined by the row unit length FP1 and the column unit length FP2. For convenience of illustration, one unit region 17 is represented as the dotted rectangular in FIG. 9b. Each unit region 17 has a row-directional length of FP1 and a column-directional length of 4*FP2. Each unit region 17 includes the one depth pixel Z and the four color pixels and the four color pixels are disposed at one side portion of each unit region 17. In other words, the four color pixels R, G, R and G included in the two left color regions are disposed at the left side portion of the dotted unit region 17 and the four color pixels G, B, G and B included in the two right color regions are disposed at the right side portion of the unit regions that are adjacent to the dotted unit region 17 in the row direction X. Accordingly, the unit regions 17 are repeatedly disposed in the row direction X and in the column direction Y, and the number ratio of the depth pixel and the color pixel in each unit region 17 corresponds to 1:4 with respect to all of the unit regions 17. In addition, the area ratio of the depth pixel and the color pixels in each unit region 17 is uniform with respect to all of the unit regions 17.

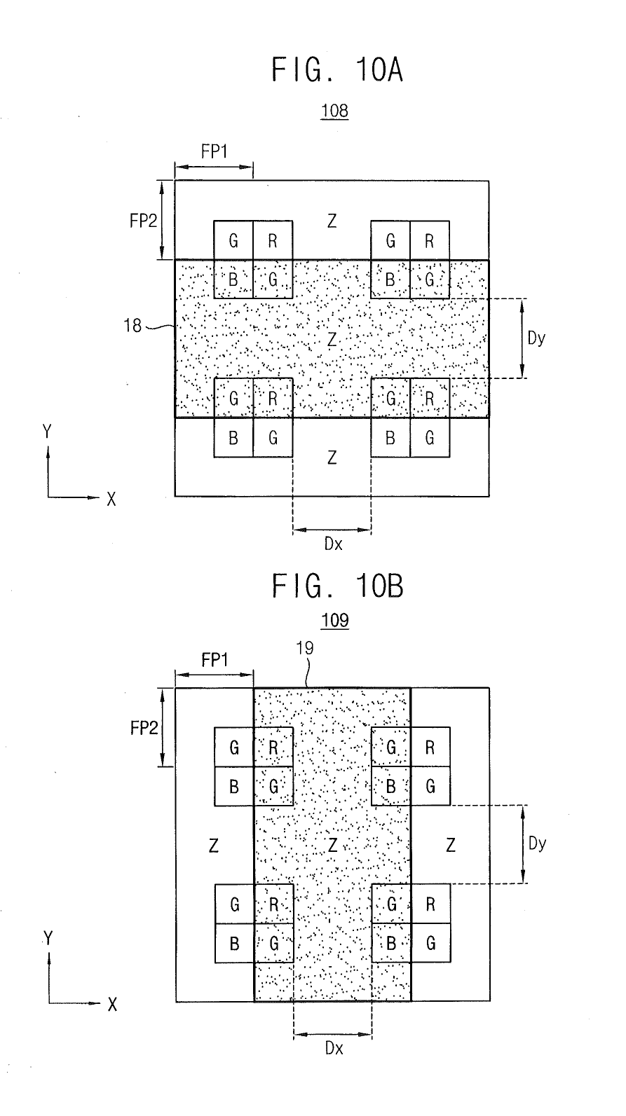

Referring to FIG. 10a, the pixel array 108 may be partitioned into unit regions such that each unit region is eight times larger than the standard cell that is defined by the row unit length FP1 and the column unit length FP2. For convenience of illustration, one unit region 18 is represented as the dotted rectangular in FIG. 10a. Each unit region 18 has a row-directional length of 4*FP1 and a column-directional length of 2*FP2. Each unit region 18 includes the one depth pixel Z and the eight color pixels and the eight color pixels are disposed at two opposite side portions of each unit region 18. In other words, the four color pixels B, G, B and G included in the two upper color regions are disposed at the upper side portion of each unit region 18 and the four color pixels G, R, G and R included in the two bottom color regions are disposed at the bottom side portion of each unit region 18. Accordingly, the unit regions 18 are repeatedly disposed in the row direction X and in the column direction Y, and the number ratio of the depth pixel and the color pixel in each unit region 18 corresponds to 1:8 with respect to all of the unit regions 18. In addition, the area ratio of the depth pixel and the color pixels in each unit region 18 is uniform with respect to all of the unit regions 18.

Referring to FIG. 10b, the pixel array 109 may be partitioned into unit regions such that each unit region is eight times larger than the standard cell that is defined by the row unit length FP1 and the column unit length FP2. For convenience of illustration, one unit region 19 is represented as the dotted rectangular in FIG. 10b. Each unit region 19 has a row-directional length of 2*FP1 and a column-directional length of 4*FP2. Each unit region 19 includes the one depth pixel Z and the eight color pixels and the eight color pixels are disposed at two opposite side portions of each unit region 19. In other words, the four color pixels R, G, R and G included in the two left color regions are disposed at the left side portion of each unit region 19 and the four color pixels G, B, G and B included in the two right color regions are disposed at the right side portion of each unit region 19. Accordingly, the unit regions 19 are repeatedly disposed in the row direction X and in the column direction Y, and the number ratio of the depth pixel and the color pixel in each unit region 19 corresponds to 1:8 with respect to all of the unit regions 19. In addition, the area ratio of the depth pixel and the color pixels in each unit region 19 is uniform with respect to all of the unit regions 19.

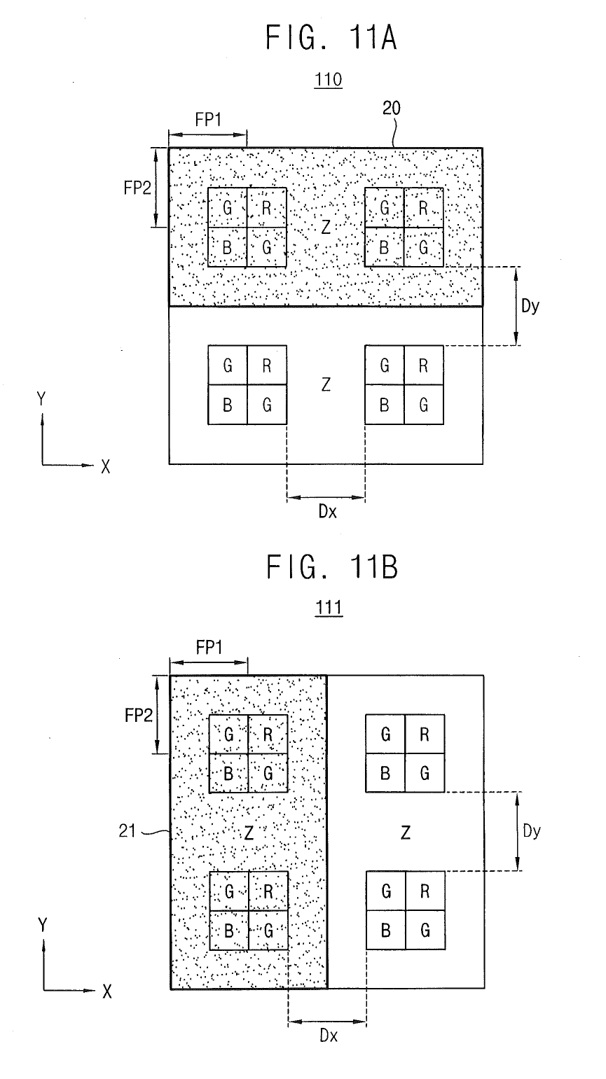

Referring to FIG. 11a, the pixel array 110 may be partitioned into unit regions such that each unit region is eight times larger than the standard cell that is defined by the row unit length FP1 and the column unit length FP2. For convenience of illustration, one unit region 20 is represented as the dotted rectangular in FIG. 11a. Each unit region 20 has a row-directional length of 4*FP1 and a column-directional length of 2*FP2. Each unit region 20 includes the one depth pixel Z and the eight color pixels and the eight color pixels are included in the two color regions adjacent to each other in the row direction X. In other words, the eight color pixels G, R, B, G, G, R, B and G included in two color regions are disposed in the matrix form of two rows and four columns within each unit region 20. Accordingly, the unit regions 20 are repeatedly disposed in the row direction X and in the column direction Y, and the number ratio of the depth pixel and the color pixel in each unit region 20 corresponds to 1:8 with respect to all of the unit regions 20. In addition, the area ratio of the depth pixel and the color pixels in each unit region 20 is uniform with respect to all of the unit regions 20.

Referring to FIG. 11b, the pixel array 111 may be partitioned into unit regions such that each unit region is eight times larger than the standard cell that is defined by the row unit length FP1 and the column unit length FP2. For convenience of illustration, one unit region 21 is represented as the dotted rectangular in FIG. 11b. Each unit region 21 has a row-directional length of 2*FP1 and a column-directional length of 4*FP2. Each unit region 21 includes the one depth pixel Z and the eight color pixels and the eight color pixels are included in the two color regions adjacent to each other in the column direction Y. In other words, the eight color pixels G, R, B, G, G, R, B and G included in two color regions are disposed in the matrix form of four rows and two columns within each unit region 21. Accordingly, the unit regions 21 are repeatedly disposed in the row direction X and in the column direction Y, and the number ratio of the depth pixel and the color pixel in each unit region 21 corresponds to 1:8 with respect to all of the unit regions 21. In addition, the area ratio of the depth pixel and the color pixels in each unit region 21 is uniform with respect to all of the unit regions 21.

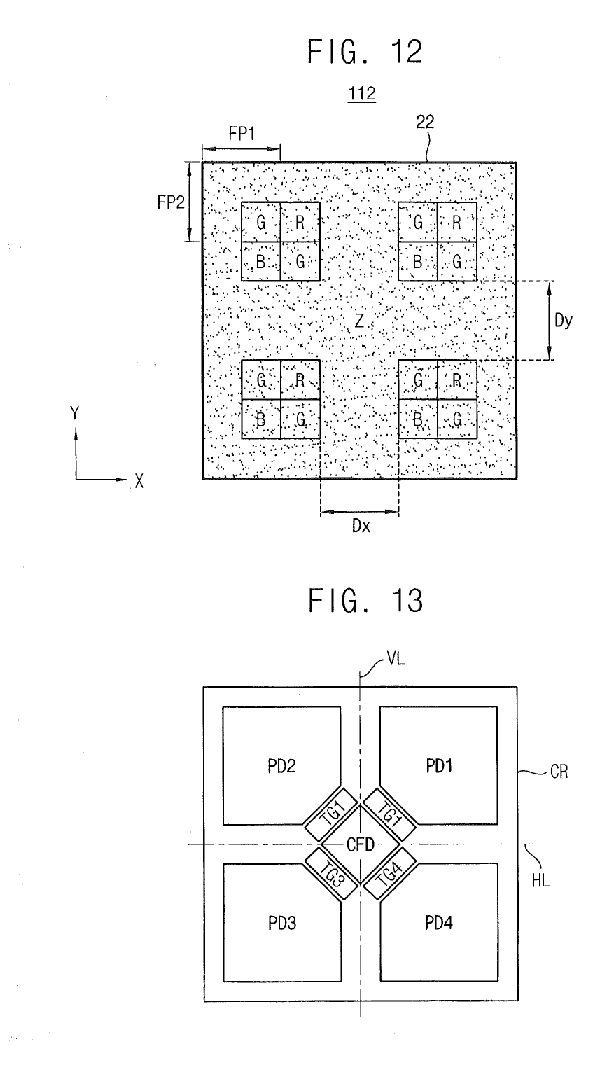

Referring to FIG. 12, the pixel array 112 may be partitioned into unit regions such that each unit region is sixteen times larger than the standard cell that is defined by the row unit length FP1 and the column unit length FP2. For convenience of illustration, one unit region 22 is represented as the dotted rectangular in FIG. 12. Each unit region 22 has a row-directional length of 4*FP1 and a column-directional length of 4*FP2. Each unit region 22 includes the one depth pixel Z and the sixteen color pixels and the sixteen color pixels are included in the four color regions. In other Words, the sixteen color pixels G, R, B, G, G, R, B, G, G, R, B, G, G, R, B and G included in four color regions are disposed in the matrix form of four rows and four columns within each unit region 22. In general, each unit region may include the one depth pixel Z and the 4 n color pixels, and the 4 n pixels in each unit region may be included in the n color regions, where n is a positive integer. Accordingly, the unit regions 22 are repeatedly disposed in the row direction X and in the column direction Y, and the number ratio of the depth pixel and the color pixel in each unit region 22 corresponds to 1:16 with respect to all of the unit regions 22. In addition, the area ratio of the depth pixel and the color pixels in each unit region 22 is uniform with respect to all of the unit regions 22.

As described with reference to the various example embodiments of FIGS. 2, 6, 7, 8a-8b, 9a-9b, 10a-10b, 11a-11b and 12, the area of the depth pixel Z may be changed variously without affecting the pattern of the color pixels R, G and B. In all of the described example embodiments, the regular pattern of the color pixels and the regular pattern of the depth pixels are maintained in the respective pixel arrays, thereby enhancing performance of the three-dimensional image sensor including the pixel array according to example embodiments.

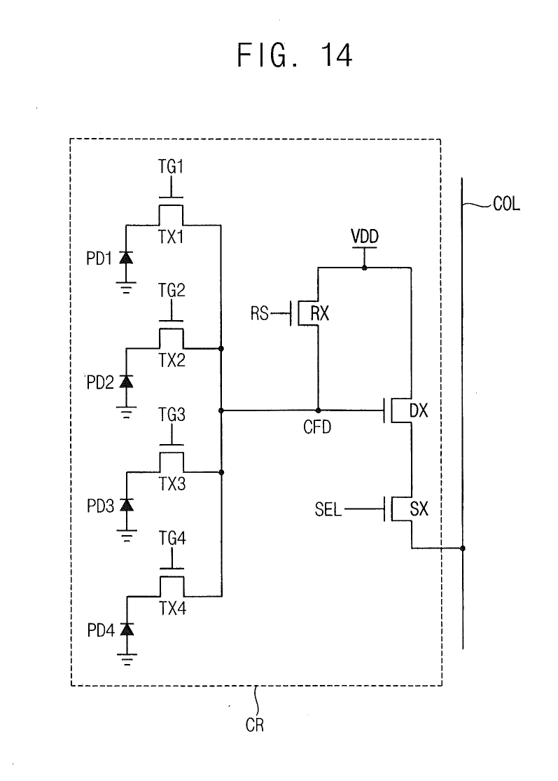

FIG. 13 is a diagram illustrating a layout of color pixels in a color region according to example embodiments, and FIG. 14 is a diagram illustrating an equivalent circuit of the color pixels of FIG. 13. Referring to FIG. 13, four color pixels may be included in each color region CR as described with reference to FIG. 2. The four photo diodes PD1, PD2, PD3 and PD4 and the four transfer gates TG1, TG2, TG3 and TG4 corresponding to the four color pixels are respectively formed in the four sub-regions divided by a vertical center line VL and a horizontal center line HL. Each of the four photo diodes PD1, PD2, PD3 and PD4 and each of the four transfer gates TG1, TG2, TG3 and TG4 are dedicated to the corresponding color pixel, but a common floating diffusion node CFD is formed in a center potion of each color region CR such that the common floating diffusion node CFD may be shared by the four color pixels in each color region CR.

Referring to FIG. 14, each color region CR may include the four photodiodes PD1, PD2, PD3 and PD4 as the photo-sensitive elements, and the four transfer transistors TX1, TX2, TX3 and TX4. For example, the one photodiode PD1, the one photo gate TG1 and the common floating diffusion node CFD form the one transfer transistor TX1. Since the common floating diffusion node CFD is shared by the four color pixels in each color region, also the reset transistor RX, the drive transistor DX and the selection transistor SX may be shared by the four color pixel. Even though not illustrated in FIG. 13, the shared transistors RX, DX and SX may be arranged along the Vertical center line VL and/or the horizontal center line HL. The readout circuit including a few transistors may be implemented variously as described with reference to FIGS. 3a-3d.

When the common floating diffusion node CFD is shared by the four color pixels, the respective charges generated in the four color pixels may be measured by controlling the activation timings of the transfer control signals TG1, TG2, TG3 and TG4 in time-division scheme. According to the configuration of the shared readout circuit of FIGS. 13 and 14, the areas of the photodiodes may be increased and thus the sensitivity of the pixels may be enhanced.

FIGS, 15, 16, 17a-17b are diagrams illustrating example layouts of a pixel array according to example embodiments. As described with reference to FIG. 1, the pixel arrays in FIGS. 15, 16, 17a-17b include the plurality of color pixels R, G and B formed in the color regions CR and the plurality of depth pixels Z formed in the depth region ZR. The color regions are spaced apart from each other by the first interval Dx in the row direction X and by the second interval Dy in the column direction Y. The depth region ZR corresponds to the empty region except the color regions CR in the pixel array region 120.

Compared with the embodiments of FIGS. 2, 6, 7, 8a-8b, 9a-9b, 10a-10b, 11a-11b and 12 in which each color region includes the four color pixels R, G, G and B arranged in a matrix form of two rows and two columns. FIGS. 15, 16, 17a-17b illustrate some example embodiments in which each color region includes the one color pixel R, G or B. In this case, the four color pixels R, G, G and B in the four color regions may form a color cluster for representing various colors. The non-limiting example embodiment is illustrated in FIGS. 15, 16, and 17a-17b, in which each color region includes one of color pixels R, G or B. In other example embodiments, each color region may include one pixel among red pixels R, green pixels G, blue pixels B, magenta pixels Mg, cyan pixels Cy, yellow pixels Y, white pixels W, etc.

The pixel array region may be partitioned into a plurality of unit regions, and each unit region of the rectangular shape includes one depth pixel Z and one or more color pixels. For example, the pixel array region may be partitioned by uniformly-spaced horizontal lines and vertical lines so that each unit region defined by the two adjacent horizontal lines and the two adjacent vertical lines has the rectangular shape. A number ratio and an area ratio of the depth pixel and the color pixels in each unit region may be uniform with respect to all of the unit regions.

Referring to FIG. 15, the pixel array 113 may be partitioned into unit regions such that each unit region has the same occupation area as a standard cell that is defined by a row unit length FP1 and a column unit length FP2. For convenience of illustration, one unit region 23 is represented as the dotted rectangular in FIG. 15. Each unit region 23 has a row-directional length of FP1 and a column-directional length of FP2. Each unit region 23 includes the one depth pixel Z and the one color pixel R, G or B, and the one color pixel is disposed at one of four corner portions of each unit region 23. FIG. 15 illustrates a non-limiting example embodiment in which the one color pixel is disposed at the right-upper corner portion of each unit region 23, and the one color pixel may be disposed at the right-bottom corner portion, the left-upper corner portion or the left-bottom corner portion of each unit region 23. Accordingly, the unit regions 23 are repeatedly disposed in the row direction X and in the column direction Y, and the number ratio of the depth pixel and the color pixel in each unit region 23 corresponds to 1:1 with respect to all of the unit regions 23. In addition, the area ratio of the depth pixel and the color pixels in each unit region 23 is uniform with respect to all of the unit regions 23.

In general, the pixel array is designed such that the pixel array region is partitioned into the standard cells defined by the row unit length FP1 and the column unit length FP2, and one depth pixel and/or one color pixel assigned to each standard cell. In this case, the pattern of the color pixels has to be damaged to increase the area of the depth pixel. In comparison, according to example embodiments, firstly the color pixels of the uniform pattern are arranged in the uniformly-spaced color regions CRs and then the depth pixels of the uniform pattern are arranged in the partitioned depth region ZR as described with reference to FIG. 1. As such, uniform patterns of the depth pixels Z and the color pixels R, G and B may be achieved to enhance the quality of the image provided by the pixel array 101, and the occupation area of the depth pixel Z may be adjusted conveniently by variously partitioning the depth region ZR corresponding to the empty region except the color regions CRs without affecting the pattern of the color pixels R, G and B.

Referring to FIG. 16, the pixel array 114 may be partitioned into unit regions such that each unit region is four times larger than the standard cell that is defined by the row unit length FP1 and the column unit length FP2. For convenience of illustration, one unit region 24 is represented as the dotted rectangular in FIG. 16. Each unit region 24 has a row-directional length of 2*FP1 and a column-directional length of 2*FP2. Each unit region 24 includes the one depth pixel Z and the four color pixels G, R, B and G, and the four color pixels G, R, B and G included in the four color regions are disposed in a matrix form of two rows and two columns within each unit region 24. Accordingly, the unit regions 24 are repeatedly disposed in the row direction X and in the column direction Y, and the number ratio of the depth pixel and the color pixel in each unit region 24 corresponds to 1:4 with respect to all of the unit regions 24. In addition, the area ratio of the depth pixel and the color pixels in each unit region 24 is uniform with respect to all of the unit regions 24.

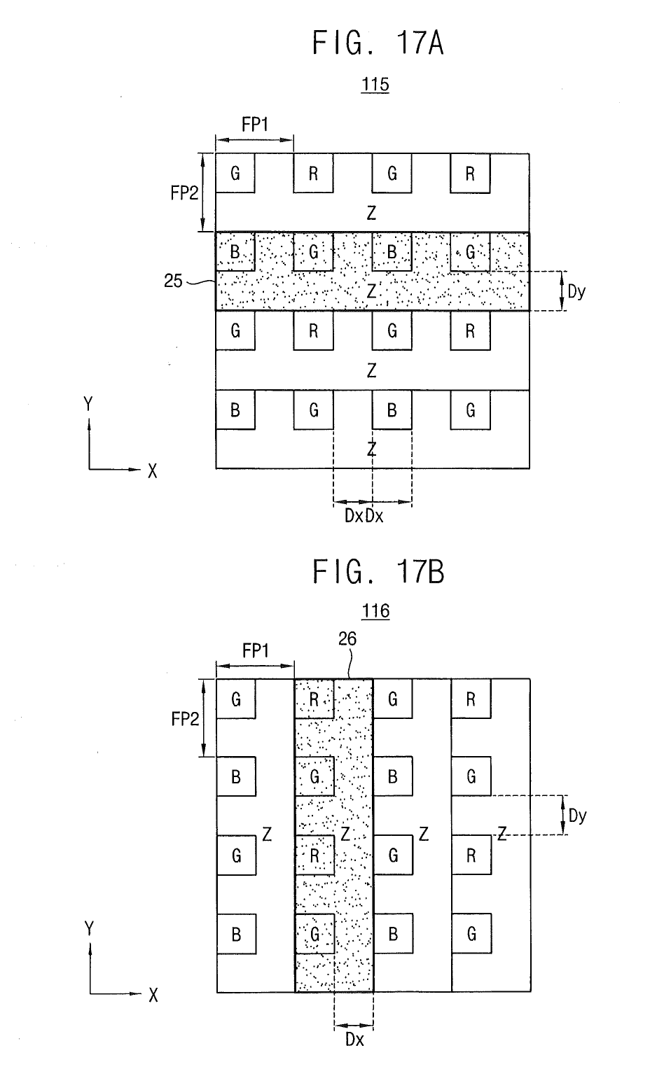

Referring to FIG. 17a, the pixel array 115 may be partitioned into unit regions such that each unit region is four times larger than the standard cell that is defined by the row unit length FP1 and the column unit length FP2. For convenience of illustration, one unit region 25 is represented as the dotted rectangular in FIG. 17a. Each unit region 25 has a row-directional length of 4*FP1 and a column-directional length of FP2. Each unit region 25 includes the one depth pixel Z and the four color pixels and the four color pixels included in the four color regions are disposed in a matrix form of one row and four columns within each unit region 25. In other words, the four color pixels B, G, B and G are disposed along the row direction X in the dotted unit region 25 and the four color pixels G, R, G and R are disposed along the row direction X in the unit regions adjacent to the dotted unit region 25 in the column direction Y. Accordingly, the unit regions 25 are repeatedly disposed in the row direction X and in the column direction Y, and the number ratio of the depth pixel and the color pixel in each unit region 25 corresponds to 1:4 with respect to all of the unit regions 25. In addition, the area ratio of the depth pixel and the color pixels in each unit region 25 is uniform with respect to all of the unit regions 25.

Referring to FIG. 17b, the pixel array 116 may be partitioned into unit regions such that each unit region is four times larger than the standard cell that is defined by the row unit length FP1 and the column unit length FP2. For convenience of illustration, one unit region 26 is represented as the dotted rectangular in FIG. 17b. Each unit region 26 has a row-directional length of FP1 and a column-directional length of 4*FP2. Each unit region 26 includes the one depth pixel Z and the four color pixels and the four color pixels included in the four color regions are disposed in a matrix form of four rows and one column within each unit region 26. In other words, the four color pixels R, G, R and G are disposed along the column direction Y in the dotted unit region 26 and the four color pixels G, B, G and B are disposed along the column direction Y in the unit regions adjacent to the dotted unit region 26 in the row direction X. Accordingly, the unit regions 26 are repeatedly disposed in the row direction X and in the column direction Y, and the number ratio of the depth pixel and the color pixel in each unit region 26 corresponds to 1:4 with respect to all of the unit regions 26. In addition, the area ratio of the depth pixel and the color pixels in each unit region 26 is uniform with respect to all of the unit regions 26.

As described with reference to the various example embodiments of FIGS. 15, 16, 17a and 17b, the area of the depth pixel Z may be changed variously without affecting the pattern of the color pixels R, G and B. In all of the described example embodiments, the regular pattern of the color pixels and the regular pattern of the depth pixels are maintained in the respective pixel arrays, thereby enhancing performance of the three-dimensional image sensor including the pixel array according to example embodiments.

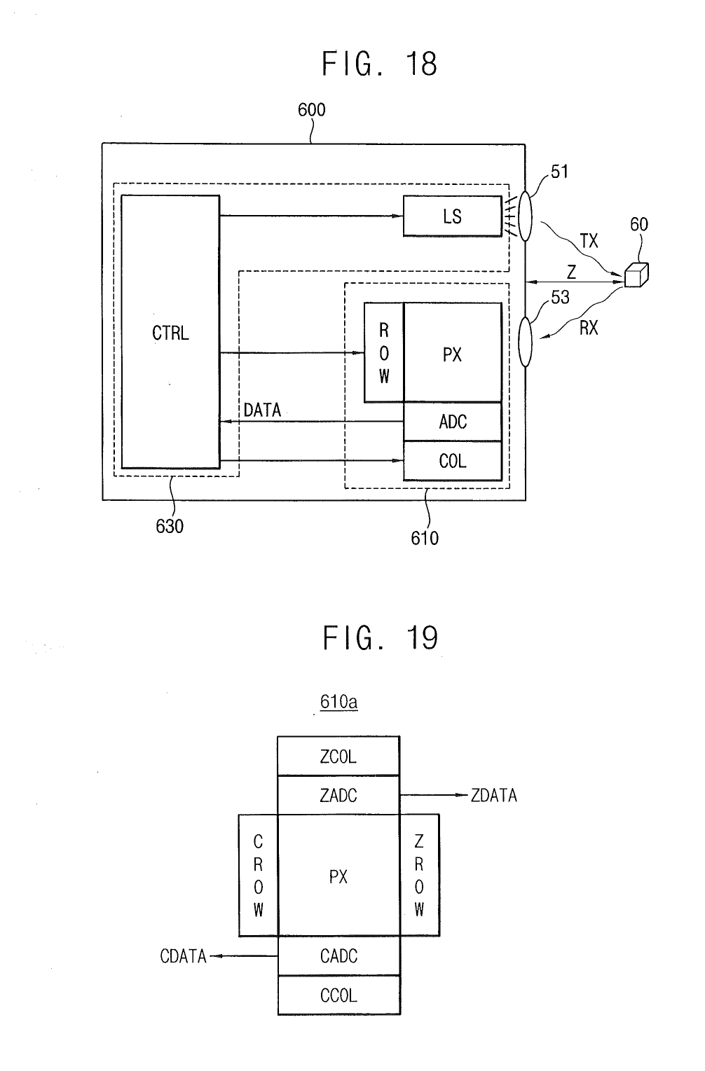

FIG. 18 is a block diagram illustrating a photo-detection device according to example embodiments. Referring to FIG. 18, the photo-detection device 600 may include a sensing unit. 610 and a control unit 630 that controls the sensing unit 610. The sensing unit 610 may include a pixel array PX, a selection circuit ROW and COL and an analog-to-digital converter ADC. The pixel array PX includes a plurality of color pixels to provide image information and a plurality of depth pixels to provide depth information. As described above, the pixel array PX is integrated in a pixel array region of a semiconductor substrate. The pixel array region includes color regions and a depth region. The color regions are spaced apart from each other by a first interval in a row direction and by a second interval in a column direction. The depth region corresponds to an empty region except the color regions in the pixel array region. The color regions are regularly arranged in a matrix form of rows and columns, and the depth region surrounds each color region.

The control unit 630 may include a light source LS that emits light TX to an object 60, and a controller CTRL that controls overall operations of the photo-detection device 600. The light source LS may emit the light TX having a predetermined wavelength. For example, the light source LS may emit infrared light or near-infrared light. The emitted light TX generated by the light source LS may be focused on the object 60 by a lens 51. The light source LS may be controlled by the controller CTRL to output the emitted light TX such that the intensity of the emitted light TX periodically changes. For example, the emitted light TX may be a pulse train signal having successive pulses. The light source LS may be implemented with a light emitting diode, a laser diode, or the like. The selection circuit ROW and COL may include the row decoder ROW and the column decoder, which are integrated near the pixel array PX to select a portion of the depth pixels and the color pixels. The analog-to-digital converter ADC may convert an output of the pixel array PX into a digital signal DATA.

In one or more embodiments, the sensing unit 610 may include a unit pixel (or a pixel group) described above, and an analog-digital converting unit ADC for converting an output of the unit pixel into a digital signal. In one or more embodiments, the sensing unit 610 may include a pixel array PX including a plurality of unit pixels (or a plurality of pixel groups) arranged in an array. In such embodiments, the sensing unit 610 may include the analog-digital converting unit ADC, and a select circuit ROW, COL for selecting a particular unit pixel in the pixel array PX.

In one or more embodiments, the analog-to-digital converter ADC may perform column analog-to-digital conversion that converts analog signals in parallel using a plurality of analog-to-digital converting units respectively coupled to a plurality of column lines, or may perform single analog-to-digital conversion that converts the analog signals in series using a single analog-digital converting unit.

In one or more embodiments, the analog-to-digital converter ADC may include a correlated double sampling (CDS) unit for extracting an effective signal component. In some embodiments, the CDS unit may perform analog double sampling (ADS) that extracts the effective signal component based on an analog reset signal that represents a reset component and an analog data signal that represents a signal component. In other embodiments, the CDS unit may perform digital double sampling (DDS) that converts the analog reset signal and the analog data signal into two digital signals to extract as the effective signal component a difference between the two digital signals. In still other embodiments, the CDS unit may perform dual correlated double sampling that performs both of analog double sampling and digital double sampling.

FIG. 19 is a diagram illustrating an example of a sensing unit in the three-dimensional image sensor of FIG. 18. More particularly, FIG. 19 illustrates an example of a sensing unit 610a in a case where the photo-detection device 600 of FIG. 19 is a three-dimensional image sensor. Referring to FIG. 19, the sensing unit 610a may include a pixel array C/Z PX where a plurality of color pixels and a plurality of depth pixels are arranged according to example embodiments, a color pixel selection circuit CROW and CCOL, a depth pixel selection circuit ZROW and ZCOL, a color pixel converter CADC and a depth pixel converter ZADC. The color pixel selection circuit CROW and CCOL and the color pixel converter CADC may provide image information CDATA by controlling the color pixels included in the pixel array C/Z PX, and the depth pixel selection circuit ZROW and ZCOL and the depth pixel converter ZADC may provide depth information ZDATA by controlling the depth pixels included in the pixel array C/Z PX. Accordingly, in the three-dimensional image sensor, components for controlling the color pixels and components for controlling the depth pixels may independently operate to provide the color data CDATA and the depth data ZDATA of an image.

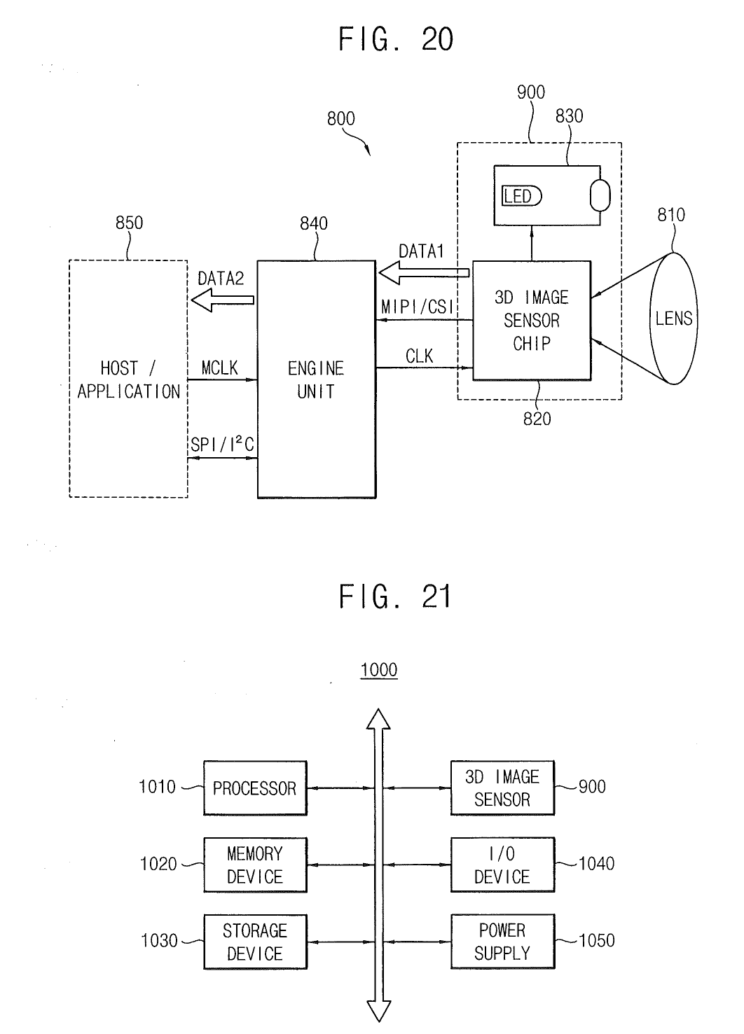

FIG. 20 is a block diagram illustrating a camera including a three-dimensional sensor according to example embodiments. Referring to FIG. 20, a camera 800 includes a photo-receiving lens 810, a three-dimensional image sensor 900 and an engine unit 840. The three-dimensional image sensor 900 may include a three-dimensional image sensor chip 820 and a light source module 830. According to embodiments, the three-dimensional image sensor chip 820 and the light source module 830 may be implemented with separated devices, or at least a portion of the light source module 830 may be included in the three-dimensional image sensor chip 820. In some embodiments, the photo-receiving lens 810 may be included in the three-dimensional image sensor chip 820.

The photo-receiving lens 810 may focus incident light on a photo-receiving region (e.g., depth pixels and/or color pixels included in a pixel array) of the three-dimensional image sensor chip 820. The three-dimensional image sensor chip 820 may generate data DATA1 including depth information and/or color image information based on the incident light passing through the photo-receiving lens 810. For example, the data DATA1 generated by the three-dimensional image sensor chip 820 may include depth data generated using infrared light or near-infrared light emitted from the light source module 830 and RGB data of a Bayer pattern generated using external visible light. The three-dimensional image sensor chip 820 may provide the data DATA1 to the engine unit 840 based on a clock signal CLK. In some embodiments, the three-dimensional image sensor chip 820 may interface with the engine unit 840 via mobile industry processor interface MIPI and/or camera serial interface CSI.

The engine unit 840 controls the three-dimensional image sensor 900. The engine unit 840 may process the data DATA1 received from the three-dimensional image sensor chip 820. For example, the engine unit 840 may generate three-dimensional color data based on the data DATA1 received from the three-dimensional image sensor chip 820. In other examples, the engine unit 840 may generate YUV data including a luminance component, a blue-luminance difference component, and a red-luminance difference component based on the RGB data included in the data DATA1, or compressed data, such as joint photography experts group (JPEG) data. The engine unit 840 may be connected to a host/application 850 and may provide data DATA2 to the host/application 850 based on a master clock MCLK. Further, the engine unit 840 may interface with the host/application 850 via serial peripheral interface (SPI) and/or inter integrated circuit (I2C).

FIG. 21 is a block diagram illustrating a computing system including a three-dimensional sensor according to example embodiments. Referring to FIG. 21, a computing system 1000 may include a processor 1010, a memory device 1020, a storage device 1030, an input/output device 1040, a power supply 1050 and a three-dimensional image sensor 900. Although it is not illustrated in FIG. 21, the computing system 1000 may further include ports that communicate with a video card, a sound card, a memory card, a USB device, or other electronic devices. The processor 1010 may perform various calculations or tasks. According to embodiments, the processor 1010 may be a microprocessor or a CPU. The processor 1010 may communicate with the memory device 1020, the storage device 1030 and the input/output device 1040 via an address bus, a control bus, and/or a data bus. In some embodiments, the processor 1010 may be coupled to an extended bus, such as a peripheral component interconnection (PCI) bus. The memory device 1020 may store data for operating the computing system 1000. For example, the memory device 1020 may be implemented with a dynamic random access memory (DRAM) device, a mobile DRAM device, a static random access memory (SRAM) device, a phase random access memory (PRAM) device, a ferroelectric random access memory (FRAM) device, a resistive random access memory (RRAM) device, and/or a magnetic random access memory (MRAM) device. The storage device may include a solid state drive (SSD), a hard disk drive (HDD), a CD-ROM, etc. The input/output device 1040 may include an input device (e.g., a keyboard, a keypad, a mouse, etc.) and an output device (e.g., a printer, a display device, etc.). The power supply 1050 supplies operation voltages for the computing system 1000.

The three-dimensional image sensor 900 may communicate with the processor 1010 via the buses or other communication links. As described above, the three-dimensional image sensor 900 may include a unit pixel having a ring-shaped structure, which operates as a single-tap detector. Further, as described above, the three-dimensional image sensor 900 may use a plurality of variable bin signals to measure a distance to an object. Accordingly, the sensitivity and the signal-to-noise ratio may be improved. The three-dimensional image sensor 900 may be integrated with the processor 1010 in one chip, or the three-dimensional image sensor 900 and the processor 1010 may be implemented as separate chips.

The three-dimensional image sensor 900 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP). The computing system 1000 may be any computing system using a three-dimensional image sensor. For example, the computing system 1000 may include a digital camera, a mobile phone, a smart phone, a portable multimedia player (PMP), a personal digital assistant (PDA), etc.

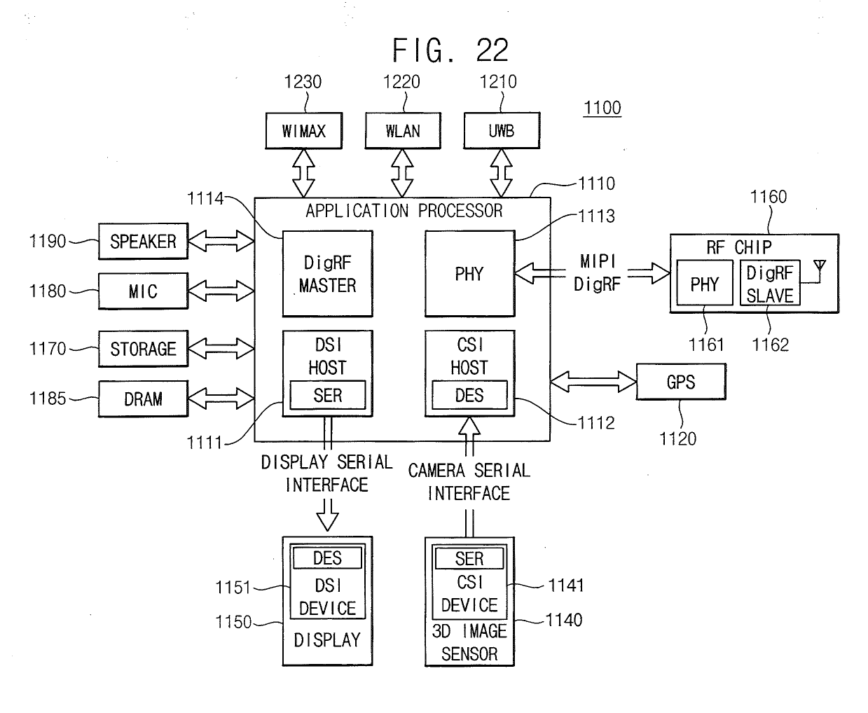

FIG. 22 is a block diagram illustrating an interface employable in the computing system of FIG. 21. Referring to FIG. 22, a computing system 1100 may be implemented by a data processing device that uses or supports a mobile industry processor interface (MIPI) interface. The computing system 1100 may include an application processor 1110, a three-dimensional image sensor 1140, a display device 1150, etc. A CSI host 1112 of the application processor 1110 may perform a serial communication with a CSI device 1141 of the three-dimensional image sensor 1140 via a camera serial interface (CSI). In some embodiments, the CSI host 1112 may include a deserializer (DES), and the CSI device 1141 may include a serializer (SER). A DSI host 1111 of the application processor 1110 may perform a serial communication with a DSI device 1151 of the display device 1150 via a display serial interface (DSI).

The DSI host 1111 may include a serializer (SER), and the DSI device 1151 may include a deserializer (DES). The computing system 1100 may further include a radio frequency (RF) chip 1160 performing a communication with the application processor 1110. A physical layer (PHY) 1113 of the computing system 1100 and a physical layer (PHY) 1161 of the RF chip 1160 may perform data communications based on a MIPI DigRF. The application processor 1110 may further include a DigRF MASTER 1114 that controls the data communications of the PHY 1161.

The computing system 1100 may further include a global positioning system (GPS) 1120, a storage 1170, a MIC 1180, a DRAM device 1185, and a speaker 1190. In addition, the computing system 1100 may perform communications using an ultra wideband (UWB) 1120, a wireless local area network (WLAN) 1220, a worldwide interoperability for microwave access (WIMAX) 1130, etc. However, the structure and the interface of the electric device 1000 are not limited thereto.

Features and/or embodiments described herein may be applied to any photo-detection device, such as a three-dimensional image sensor providing image information and depth information about an object. For example, one or more embodiments may be applied to a computing system, such as a face recognition security system, a desktop computer, a laptop computer, a digital camera, a three-dimensional camera, a video camcorder, a cellular phone, a smart phone, a personal digital assistant (PDA), a scanner, a video phone, a digital television, a navigation system, an observation system, an auto-focus system, a tracking system, a motion capture system, an image-stabilizing system, etc. Example embodiments may be adopted in a three-dimensional image sensor and an associated system. For example, example embodiments may be adopted in a mobile phone, a smart phone, a multimedia player, a digital camera, a computer, a notebook, a game console, a navigation system, a video phone, a tracking system, a motion detection system, an image stabilizing system, a face detection security system, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A three-dimensional color image sensor, comprising:
a semiconductor substrate comprising a depth region extending adjacent a surface thereof and a two-dimensional array of spaced-apart color regions within the depth region, said color regions respectively comprising a plurality of different color pixels.

2. The image sensor of claim 1, wherein the color pixels within each of the spaced-apart color regions are spaced-apart from all other color pixels within other color regions.

3. The image sensor of claim 2, wherein the depth region comprises a plurality of depth pixels therein; and wherein each of the color regions is surrounded on all sides by the depth region.

4. The image sensor of claim 3, wherein each of the spaced-apart color regions comprises a blue pixel, a red pixel and a plurality of green pixels.

5. The image sensor of claim 4, wherein each green pixel in a color region is separated from a green pixel in another color region by at least one depth pixel.

6. A pixel array of a three-dimensional image sensor, the pixel array being integrated in a pixel array region of a semiconductor substrate, comprising:
a plurality of color pixels formed in color regions in the pixel array region, the color regions being spaced apart from each other by a first interval in a row direction and by a second interval in a column direction; and
a plurality of depth pixels formed in a depth region in the pixel array region, the depth region corresponding to an empty region except the color regions in the pixel array region.

7. The pixel array of claim 6, wherein the pixel array region is partitioned into a plurality of unit regions, each unit region having a rectangular shape and including the one depth pixel and the at least one color pixel such that a number ratio and an area ratio of the one depth pixel and the at least one color pixel in each unit region are uniform with respect to all of the unit regions.

8. The pixel array of claim 7, wherein each color region includes the four color pixels arranged in a matrix form of two rows and two columns.

9. The pixel array of claim 8, wherein each unit region includes the one depth pixel and the one color pixel, and the one color pixel is disposed at one of four corner portions of each unit region.

10. The pixel array of claim 8, wherein each unit region includes the one depth pixel and the four color pixels, and the four color pixels are disposed at four corner portions of each unit region, respectively.

11. The pixel array of claim 8, wherein each unit region includes the one depth pixel and the four color pixels, and the four color pixels are disposed at a center portion of each unit region.

12. The pixel array of claim 8, wherein each unit region includes the one depth pixel and the four color pixels, and the four color pixels are disposed at upper and bottom side portions of each unit region two by two or the four color pixels are disposed at right and left side portions of each unit region two by two.

13. The pixel array of claim 8, wherein each unit region includes the one depth pixel and the at least two color pixels, and the at least two color pixels are disposed at one side portion of each unit region or the at least two color pixels are disposed at two opposite side portions of each unit region.

14. The pixel array of claim 8, wherein each unit region includes the one depth pixel and the 4 n color pixels, and the 4 n pixels in each unit region are included in the n color regions, where n is a positive integer.

15. The pixel array of claim 8, wherein a common floating diffusion node is formed in a center potion of each color region such that the common floating diffusion node is shared by the four color pixels in each color region.

16. The pixel array of claim 7, wherein each color region includes the one color pixel.

17. The pixel array of claim 16, wherein each unit region includes the one depth pixel and the one color pixel, and the one color pixel is disposed at one of four corner portions of each unit region.

18. The pixel array of claim 16, wherein each unit region includes the one depth pixel and the at least one color pixel, and the at least one color pixel is arranged in a matrix form of at least one row and at least one column.

19. A three-dimensional image sensor comprising:
a pixel array integrated in a pixel array region of a semiconductor substrate, the pixel array including,
a plurality of color pixels formed in color regions in the pixel array region, the color regions being spaced apart from each other by a first interval in a row direction and by a second interval in a column direction, and
a plurality of depth pixels formed in a depth region in the pixel array region, the depth region corresponding to an empty region except the color region in the pixel array region:
an analog-to-digital converter configured to convert analog signals from the pixel array to digital signals; and
a selection circuit configured to select a portion of the depth pixels and the color pixels.

20. The three-dimensional image sensor of claim 19, wherein the pixel array region is partitioned into a plurality of unit regions, each unit region having a rectangular shape and including the one depth pixel and the at least one color pixel such that a number ratio and an area ratio of the one depth pixel and the at least one color pixel in each unit region are uniform with respect to all of the unit regions.
